(19) United States
(12) Patent Application Publication
(10) Pub. No.: US 2008/0284038 A1
(43) Pub. Date: Nov. 20, 2008

(54) INTEGRATED CIRCUIT PACKAGE SYSTEM WITH PERIMETER PADDLE

(76) Inventors: Antonio B. Dimaano, JR., Singapore (SG); Sheila Marie L. Alvarez, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 11/749,712

(22) Filed: May 16, 2007

(51) Int. Cl. H01L 23/48

(52) U.S. Cl. 257/774; 257/E23.01

(57) ABSTRACT

An integrated circuit package system is provided including forming a perimeter paddle having a first external interconnect extending therefrom, mounting an integrated circuit die over the perimeter paddle, connecting a second external interconnect and the integrated circuit die, and encapsulating the integrated circuit die and the perimeter paddle with the first external interconnect exposed.

### TECHNICAL FIELD

The present invention relates generally to an integrated circuit package system, and more particularly to an integrated circuit package system with die-attach paddle.

### BACKGROUND ART

Modern consumer electronics, such as cellular phones, digital cameras, and music players, are packing more integrated circuits into an ever-shrinking physical space with expectations for decreasing cost. Numerous technologies have been developed to meet these requirements. Some of the research and development strategies focus on new technologies while others focus on improving the existing and mature technologies. Research and development in the existing technologies may take a myriad of different directions.

Consumer electronics requirements demand more integrated circuits in an integrated circuit package while paradoxically providing less physical space in the system for the increased integrated circuits content. Continuous cost reduction is another requirement. Some technologies primarily focus on integrating more functions into each integrated circuit. Other technologies focus on stacking these integrated circuits into a single package. While these approaches provide more functions within an integrated circuit, they do not fully address the requirements for lower height, smaller space, and cost reduction.

One proven way to reduce cost is to use mature package technologies with existing manufacturing methods and equipments. Paradoxically, the reuse of existing manufacturing processes does not typically result in the reduction of package dimensions. Still the demand continues for lower cost, smaller size and more functionality. Continued integration of functions into a single integrated circuit increases the integrated circuit size necessitating a more expensive package or a higher profile package.

Electronic products and integrated circuit inside are subjected to the full range of environments and conditions. This can span negative temperatures, triple digit temperatures, moisture, altitude, high force impacts and repetitive stress. Manufacturing methods need to accommodate both fabrication extremes as well as application or usage extremes. Stresses often result in damage to the integrated circuit package, such as delamination, corrosion, and breakage. This damage causes failures that are sometimes intermittent and hard to detect or analyze.

A variation of existing technologies uses integrated circuit packages with a die-attach paddle. Typically, integrated circuit die mounts on the die-attach paddle, wherein the die-attach paddle provides support and planar rigidity. Although conventional die-attach paddles provide functional utility, they create other problems. For example, the encapsulation may separate from the die-attach, such as epoxy molding compound (EMC) delamination, causing reliability problems, such as test failures in moisture sensitivity level (MSL) test.

Thus, a need still remains for an integrated circuit package system providing low cost manufacturing, improved yield, and improved reliability. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including mounting an integrated circuit die having a non-active side on a perimeter paddle with an adhesive with the non-active side facing the perimeter paddle, connecting an active side of the integrated circuit die to an external interconnect, and forming an encapsulation over the integrated circuit die and the perimeter paddle.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a bottom view of an integrated circuit package system in a first embodiment of the present invention;

FIG. 2 is a plan view of the integrated circuit package system;

FIG. 3 is a top view of the perimeter paddle with the adhesive thereon;

FIG. 4 is a cross-sectional view of the integrated circuit package system along line 4-4 of FIG. 1;

FIG. 5 is a cross-sectional view of an integrated circuit package system in a second embodiment of the present invention; and

FIG. 6 is a flow chart of an integrated package system for manufacturing the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs.

In addition, where multiple embodiments are disclosed and described having some features in common, for clarity and ease of illustration, description, and comprehension thereof, similar and like features one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

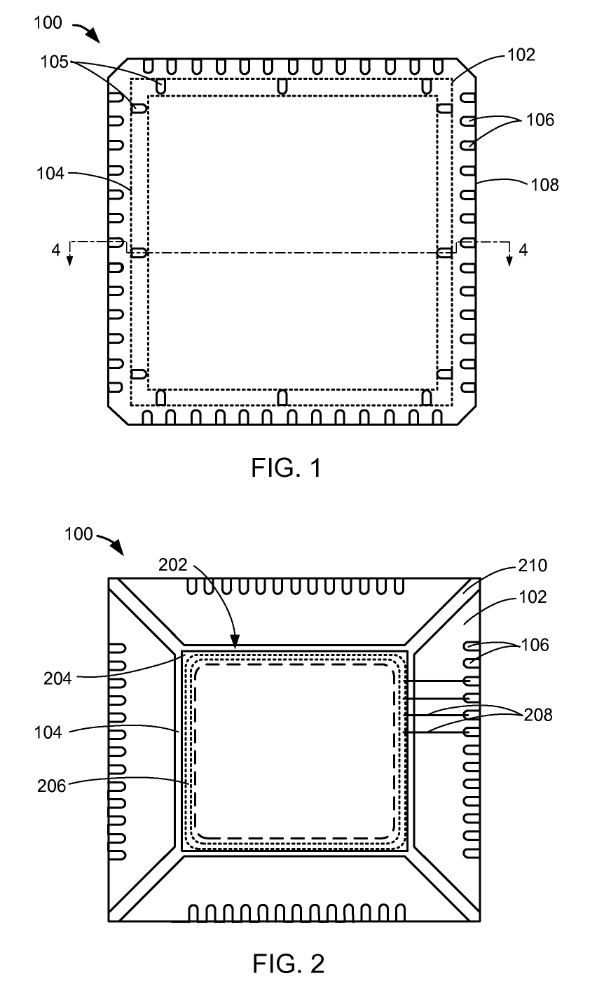

Referring now to FIG. 1, therein is shown a bottom view of an integrated circuit package system 100 in a first embodiment of the present invention. The bottom view depicts an encapsulation 102, such as an epoxy molding compound, encapsulating a perimeter paddle 104, such as a die-attached paddle, of which is shown partially exposed through the encapsulation 102. The perimeter paddle 104 is depicted by a dotted rectangular ring. The partially exposed portions of the perimeter paddle 104 are shown as first external interconnects 105, such as inner leads, of the integrated circuit package system 100.

Second external interconnects 106, such as outer leads, are preferably along edges 108 of the integrated circuit package system 100 providing access for electrical connections to the integrated circuit package system 100 for connections with the next system level (not shown), such as a printed circuit board or another integrated circuit device. The first external interconnects 105 provide access for electrical connections to the integrated circuit package system 100 for connections with the next system level.

For illustrative purposes, the perimeter paddle 104 is shown partially exposed by the encapsulation 102, although it is understood that the perimeter paddle 104 may not be partially, such as fully exposed or not exposed from the bottom view. Also for illustrative purposes, the perimeter paddle 104 is shown partially exposed equally along each of the edges 108, although it is understood that the perimeter paddle 104 may not be exposed equally along each of the edges 108.

Referring now to FIG. 2, therein shown is a plan view of the integrated circuit package system 100. The plan view depicts the integrated circuit package system 100 without a top portion of the encapsulation 102. The plan view also depicts an integrated circuit die 202 mounted over the perimeter paddle 104. The integrated circuit die 202 has an active side 204 having active circuitry fabricated thereon. The active side 204 faces away from the perimeter paddle 104 with the integrated circuit die 202 mounts on the perimeter paddle 104 preferably with an adhesive 206, such as a die-attach adhesive, dispensed adhesive, or a film adhesive. The adhesive 206 is depicted as a dotted ring.

The integrated circuit die 202 is electrically connected to the perimeter paddle 104 and the second external interconnects 106 with inner interconnects 208, such as bond wires or ribbon bonds wires. The inner interconnects 208 electrically connect the active side 204 of the integrated circuit die 202 with a predetermined selection of the second external interconnects 106. Also, the inner interconnects 208 may preferably connect the active side 204 and tie bars 210, wherein the tie bars 210 are connected with the perimeter paddle 104. The tie bars 210 may preferably also be electrically connected to a reference level through the first external interconnects 105 of FIG. 1. The encapsulation 102 encapsulate the integrated circuit die 202, the perimeter paddle 104, and the inner interconnects 208 to form the integrated circuit package system 100.

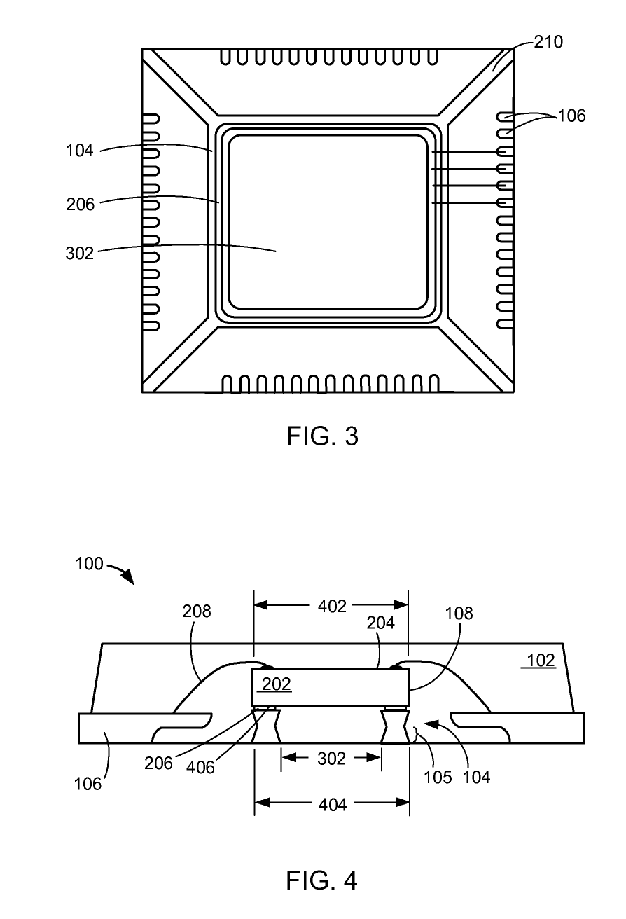

Referring now to FIG. 3, therein is a top view of the perimeter paddle 104 with the adhesive 206 thereon. The perimeter paddle 104 comprises an electrically conductive material, such as of metal, formed preferably in a continuous geometric configuration, such as the rectangular ring configuration having a central opening 302. For illustrative purposes, the perimeter paddle 104 is shown with a rectangular ring configuration, although it is understood that the perimeter paddle 104 may be formed in other geometric configurations, of various size and shape having the central opening 302.

The tie bars 210 are connected to corners of the perimeter paddle 104. The adhesive 206 on the perimeter paddle 104 may be applied in a number of different configurations or applied by a number of different processes. For example, the adhesive 206 may be applied by dispensing or attaching a film adhesive. Another example, the adhesive 206 may be applied in a variety of configurations, such as in a contiguous configuration or a non-contiguous configuration. The application of the adhesive 206 on the perimeter paddle 104 provides cost reduction compared to the amount of the adhesive 206 that would be applied on a paddle (not shown) without the central opening 302. The second external interconnects 106 are adjacent to the tie bars 210 and the perimeter paddle 104.

Referring now to FIG. 4, therein is shown a cross-sectional view of the integrated circuit package system 100 along line 4-4 of FIG. 1. The cross-sectional view of the integrated circuit package system 100 depicts the integrated circuit die 202 having a device width 402 mounted over the perimeter paddle 104 having a paddle width 404 with the adhesive 206. A non-active side 406 of the integrated circuit die 202 faces the perimeter paddle 104. The non-active side 406 is a side opposite the active side 204 of the integrated circuit die 202. The device width 402 is preferably less than the paddle width 404 such that the integrated circuit die 202 does not overhang the perimeter paddle 104, also the device width 402 may be equal to the paddle width 404. The device width 402 is greater than the width of the central opening 302 of the perimeter paddle 104.

The central opening 302 in the perimeter paddle 104 mitigates or eliminates delamination of the encapsulation 102 and the perimeter paddle 104. The perimeter paddle 104 having the first external interconnects 105 extending therefrom forms mold locking features improving moisture sensitivity level (MSL) test performance and improving reliability of the integrated circuit package system 100.

The second external interconnects 106, such as outer leads, are preferably along the edges 108 of the integrated circuit package system 100 providing access for electrical connections to the integrated circuit package system 100 for connections with the next system level (not shown), such as a printed circuit board or another integrated circuit device. The encapsulation 102 exposes the first external interconnects 105 of the perimeter paddle 104, wherein the first external interconnects 105 may preferably function as inner leads for the integrated circuit package system 100.

The first external interconnects 105 may be formed with a number of different ways. For example, the perimeter paddle 104 may be partially or half etched at predetermined locations. The non-etched portions of the perimeter paddle 104 are exposed from the encapsulation 102 forming the first external interconnects 105 and may preferably function as the inner leads for the integrated circuit package system 100. The first external interconnects 105 may be considered as extending from the partially etched portions of the perimeter paddle 104, wherein the partially etched portions are within the encapsulation 102.

As described earlier, the first external interconnects 105 of the perimeter paddle 104 provide may be used for electrical connections to the integrated circuit package system 100 for connections with the next system level. For illustrative purposes, the first external interconnects 105 of the perimeter paddle 104 are shown exposed from the encapsulation 102. Although, it is understood that more or less number of the first external interconnects 105 of the perimeter paddle 104 may be exposed potentially serving as the inner leads. Also for illustrative purposes, the perimeter paddle 104 is shown as partially exposed with the first external interconnects 105, although it is understood that the perimeter paddle 104 may be fully exposed seen from the bottom view.

The integrated circuit die 202 preferably connects with the second external interconnects 106 with the inner interconnects 208, such as bond wires or ribbon bonds wires. The inner interconnects 208 connect the active side 204 of the integrated circuit die 202 with a predetermined selection of the second external interconnects 106. Also, the inner interconnects 208 may preferably connect the active side 204 and the tie bars 210 of FIG. 2, wherein the tie bars 210 are connected with the perimeter paddle 104 and the first external interconnects 105. The encapsulation 102 encapsulates the integrated circuit die 202, the perimeter paddle 104, and the inner interconnects 208 forming the integrated circuit package system 100.

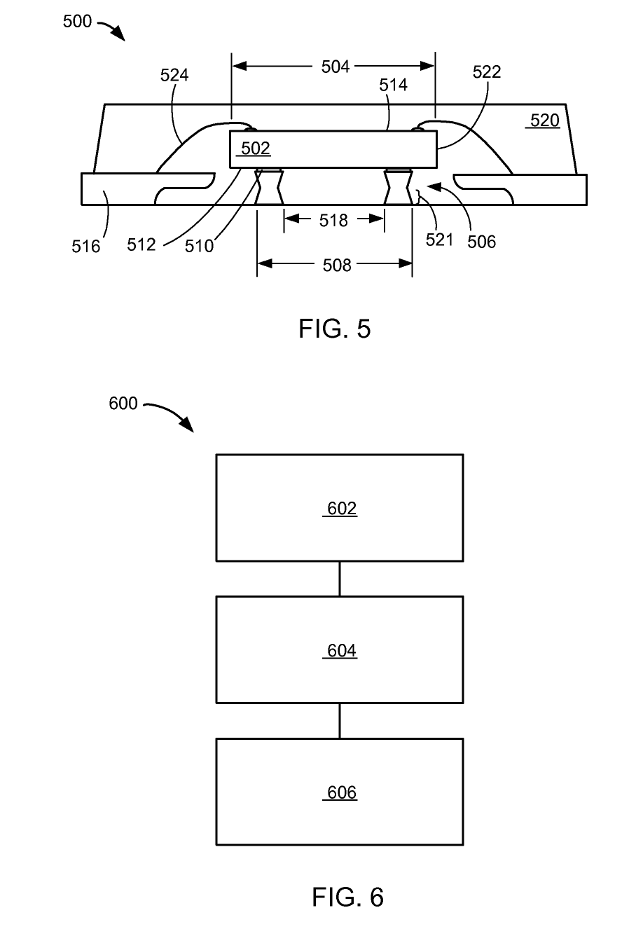

Referring now to FIG. 5, therein is shown a cross-sectional view of an integrated circuit package system 500 in a second embodiment of the present invention. The bottom view of the integrated circuit package system 100 of FIG. 1 may represent the bottom view for the integrated circuit package system 500. The cross-sectional view of the integrated circuit package system 500 is also along 4-4 of FIG. 1. The integrated circuit package system 500 has structural similarities to the integrated circuit package system 100.

The cross-sectional view of the integrated circuit package system 500 depicts an integrated circuit die 502 having a device width 504 mounted over a perimeter paddle 506 having a paddle width 508 with an adhesive 510, such as a dispensed or a film die-attached adhesive. A non-active side 512 of the integrated circuit die 502 faces the perimeter paddle 506. The non-active side 512 is a side opposite an active side 514 of the integrated circuit die 502, wherein the active side 514 has active circuitry fabricated thereon. The device width 504 is preferably greater than the paddle width 508 such that the integrated circuit die 502 overhangs the perimeter paddle 506 and can be adhering to the tie bars 210 of FIG. 2 as well. The device width 504 is less than the distance between second external interconnects 516 at opposite sides of the integrated circuit package system 500.

A central opening 518 in the perimeter paddle 506 mitigates or eliminates delamination of an encapsulation 520, such as an epoxy molding compound, and the perimeter paddle 506. The encapsulation 520 exposes first external interconnects 521 of the perimeter paddle 506, wherein the first external interconnects 521 may preferably function as inner leads for the integrated circuit package system 500. The perimeter paddle 506 having the first external interconnects 521 extending therefrom forms mold locking features improving performance in moisture sensitivity level (MSL) tests and improving reliability of the integrated circuit package system 500.

The second external interconnects 516, such as outer leads, are preferably along edges 522 of the integrated circuit package system 500 providing access for electrical connections to the integrated circuit package system 500 for connections with the next system level (not shown), such as a printed circuit board or another integrated circuit device. The encapsulation 520 exposes the first external interconnects 521 of the perimeter paddle 506, wherein the first external interconnects 521 may function as inner leads for the integrated circuit package system 500.

The first external interconnects 521 may be formed with a number of different ways. For example, the perimeter paddle 506 may be partially or half etched at predetermined locations. The non-etched portions of the perimeter paddle 506 form the first external interconnects 521 and are exposed from the encapsulation 520.

The first external interconnects 521 may be used for electrical connections to the integrated circuit package system 500 for connections with the next system level. For illustrative purposes, the perimeter paddle 506 is shown partially exposed with the first external interconnects 521 from the encapsulation 520. Although, it is understood that more or less of the first external interconnects 521 of the perimeter paddle 506 may be exposed potentially serving as the inner leads. Also for illustrative purposes, the perimeter paddle 506 is shown as partially exposed with the first external interconnects 521, although it is understood that the perimeter paddle 506 may be fully exposed seen from the bottom view.

The integrated circuit die 502 preferably connects with the second external interconnects 516 with inner interconnects 524, such as bond wires or ribbon bonds wires. The inner interconnects 524 connect the active side 514 of the integrated circuit die 502 with a predetermined selection of the second external interconnects 516. Also, the inner interconnects 524 may preferably connect the active side 514 and tie bars (not shown), wherein the tie bars, such as the tie bars 210 of FIG. 2, are connected with the perimeter paddle 506. The encapsulation 520 encapsulates the integrated circuit die 502, the perimeter paddle 506, and the inner interconnects 524 forming the integrated circuit package system 500.

Referring now to FIG. 6, therein is shown a flow chart of an integrated circuit package system 600 for manufacturing the integrated circuit package system 100 in an embodiment of the present invention. The system 600 includes forming a perimeter paddle having a first external interconnect extending therefrom in a block 602; mounting an integrated circuit die over the perimeter paddle in a block 604; connecting a second external interconnect and the integrated circuit die in a block 606; and encapsulating the integrated circuit die and the perimeter paddle with the first external interconnect exposed in a block 608.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit package system of the present invention furnishes important and heretofore unknown and unavailable solutions, capabilities, and functional aspects for improving yield, increasing reliability, and reducing cost of integrated circuit package system. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
forming a perimeter paddle having a first external interconnect extending therefrom;
mounting an integrated circuit die over the perimeter paddle;
connecting a second external interconnect and the integrated circuit die; and
encapsulating the integrated circuit die and the perimeter paddle with the first external interconnect exposed.

2. The system as claimed in claim 1 further comprising applying an adhesive in a contiguous configuration or a non-contiguous configuration on the perimeter paddle.

3. The system as claimed in claim 1 further comprising applying a film adhesive on the perimeter paddle.

4. The system as claimed in claim 1 wherein forming the perimeter paddle includes forming the first external interconnect by partially etching the perimeter paddle.

5. The system as claimed in claim 1 wherein forming the perimeter paddle includes forming a central opening in the perimeter paddle.

6. An integrated circuit package system comprising:
forming a perimeter paddle having both a first external interconnect extending therefrom and a central opening;
mounting an integrated circuit die over the perimeter paddle with an adhesive;
connecting a second external interconnect and the integrated circuit die; and
encapsulating the integrated circuit die and the perimeter paddle with the first external interconnect and the second external interconnect exposed.

7. The system as claimed in claim 6 wherein:
forming the perimeter paddle includes:
forming a tie bar connected with the perimeter paddle; and
connecting the active side further includes:
connecting the tie bar and the integrated circuit die.

8. The system as claimed in claim 6 wherein forming the perimeter paddle having both the first external interconnect extending therefrom and the central opening includes forming a mold locking feature.

9. The system as claimed in claim 6 further comprising connecting the first external interconnect to a reference level.

10. The system as claimed in claim 6 wherein mounting the integrated circuit die includes overhanging the integrated circuit die over the perimeter paddle.

11. An integrated circuit package system comprising:
a perimeter paddle having a first external interconnect extending therefrom;
an integrated circuit die over the perimeter paddle;
a second external interconnect connected to the integrated circuit die; and
an encapsulation over the integrated circuit die and the perimeter paddle with the first external interconnect exposed.

12. The system as claimed in claim 11 further comprising an adhesive in a contiguous or a non-contiguous configuration on the perimeter paddle.

13. The system as claimed in claim 11 further comprising a film adhesive on the perimeter paddle.

14. The system as claimed in claim 11 wherein the perimeter paddle is partially exposed from the encapsulation.

15. The system as claimed in claim 11 wherein the perimeter paddle includes a central opening.

16. The system as claimed in claim 11 wherein:
the perimeter paddle has a central opening; and
further comprising:
an adhesive over the perimeter paddle.

17. The system as claimed in claim 16 further comprising a tie bar connected with the perimeter paddle, wherein the tie bar is connected with the integrated circuit die.

18. The system as claimed in claim 16 wherein the perimeter paddle having both the first external interconnect extending therefrom and the central opening is a mold locking feature.

19. The system as claimed in claim 16 further comprising the first external interconnect connected to a reference level.

20. The system as claimed in claim 16 wherein the integrated circuit die overhangs the perimeter paddle.
